(19) United States
(12) Patent Application Publication
(10) Pub. No.: US 2013/0229207 A1
(43) Pub. Date: Sep. 5, 2013

(54) FLOATING GATE DRIVER WITH BETTER SAFE OPERATION AREA AND NOISE IMMUNITY, AND METHOD FOR LEVEL SHIFTING A SWITCH SIGNAL

(71) Applicant: RICHTEK TECHNOLOGY CORPORATION, Chupei City (TW)

(72) Inventors: Pei-Kai TSENG, Keelung City (TW); Chien-Fu TANG, Hsinchu City (TW); Isaac Y. CHEN, Jubei City (TW)

(73) Assignee: RICHTEK TECHNOLOGY CORPORATION, Chupei City (TW)

(21) Appl. No.: 13/778,865

(22) Filed: Feb. 27, 2013

(30) Foreign Application Priority Data
Mar. 2, 2012 (TW) 101107103

(51) Int. Cl. H03K 19/003; H03K 19/0175

(52) U.S. Cl. CPC H03K 19/00361; H03K 19/017509
USPC 327/109; 327/333

(57) ABSTRACT

A floating gate driver includes a level shifter to transmit a set signal and a reset signal to a first output terminal and a second output terminal, respectively. The level shifter includes a first high-voltage transistor, a first current limiter and a first input transistor connected in series between the first output terminal and a ground terminal, and a second high-voltage transistor, a second current limiter and a second input transistor connected in series between the second output terminal and the ground terminal, and the first and second high-voltage transistors are remained on. With this arrangement, the level shifter can transmit signals from low side to high side under better safe operating area and has better noise immunity.

### FIELD OF THE INVENTION

The present invention is related generally to a floating gate driver and, more particularly, to a circuit and method for improving the safe operating area and noise immunity of a level shifter in a floating gate driver.

### BACKGROUND OF THE INVENTION

The high-voltage integrated circuit (HVIC) is necessary for high-voltage applications, such as motor, ballast, two inductor one capacitor (LLC), and cold cathode fluorescent lamp (CCFL). For example, referring to the floating gate driver shown in FIG. 1, a controller IC 10 generates gate control signals Vh and VI according to switch signals Hin and Lin for switching a high-side power transistor Ht and a low-side power transistor Lt in a half H-bridge circuit, respectively, in order to reduce the voltage to which the high-side circuit will be subjected, the voltage Vs at the switching node SX of the half H-bridge circuit is used as the reference potential of the high-side circuit, and the low-voltage switch signal HIN referenced to a low-voltage logic signal generated at the ground terminal GND is shifted to a higher level to generate the gate control signal Vh for the high-side power transistor Ht. To shift the level of the switch signal HIN, referring to FIG. 1 and FIG. 2, a pulse generator 12 detects the rising edge and the falling edge of the switch signal HIN to trigger a set signal Set and a reset signal Reset, respectively, both of which are short-pulse signals, a level shifter 14 includes input transistors M1 and M2 to receive the set signal Set and the reset signal Reset, respectively, and thereby inducing a negative pulse in an output voltage VAA at an output terminal AA of the level shifter 14 and a negative pulse in an output voltage VBB at an output terminal BB of the level shifter 14, respectively, and a logic regeneration circuit 16 generates a signal as being level shifted from the switch signal Hin responsive to the negative pulse in the output voltage VAA and the negative pulse in the output voltage VBB. The level shifted signal has the same logic state as the switch signal Hin, and the gate control signal Vh generated from the level shifted signal is triggered by the set signal Set and terminated by the reset signal Reset.

In this floating gate driver, transient variation of the voltage Vs at the switching node SX will induce a voltage noise at each of the output terminals AA and BB of the level shifter 14 via the bootstrap capacitor Cboot coupled between the direct-current (DC) power input terminal Vboot and the switching node SX. The voltage noise may lead to erroneous action of the logic regeneration circuit 16 or even cause the high-side power transistor Ht and the low-side power transistor Lt to be turned on at same time. Should the latter occur, the DC power supply VCC will be directly short to the ground terminal GND. In order to improve the noise immunity of the level shifter 14, U.S. Patent Application Publication No. 2011/0006828 replaces the input transistors M1 and M2 with a differential input pair so that, under the limitation of a fixed common bias current, any charging/discharging current resulting from noise will be shared out between the two transistors in the differential input pair to reduce the amplitude of the noise voltage at each of the output terminals AA and BB. However, with the two transistors in the differential input pair being tied together by a common bias current source, this art disadvantageously increases the chances of interference between the two transistors.

On the other hand, the high-side circuit must be made by an ultra-high voltage (UHV) manufacturing process, which is very expensive and raises the costs of the controller IC 10 significantly. One way to cut costs is to use a multi-chip module (MCM). For example, referring to FIG. 1, the dashed line 18 served as a boundary divides the floating gate driver into two parts. The high-side circuit and a portion of the level shifter 14 are made in a UHV chip and are shown as lying above the dashed line 18. The low-side circuit and the other portion of the level shifter 14 are made in a low-voltage chip and are shown as lying below the dashed line 18. Thus, the circuit and size of the UHV chip are decreased, and consequently the costs of the UHV chip can be reduced. However, as the signal transmission from the low side to the high side of this MCM is in voltage form, and an MCM typically has low noise immunity when transmitting voltage signals, the noise immunity of the level shifter 14 is reduced.

Furthermore, the input transistors M1 and M2 located between the high-side circuit and the low-side circuit must be high-voltage components, so the design of the controller IC 10 entails a compromise between breakdown voltages of the input transistors M1 and M2 and other parameters. While increasing the sizes of the transistors M1 and M2 helps raise the breakdown voltages thereof, the area and costs of the IC will be increased, too. Now that a UHV manufacturing process is required, it is especially disadvantageous to increase the input transistors M1 and M2 in size. In order to provide a better safe operating area, it is common practice to adjust the working points of the input transistors M1 and M2. Take an n-type metal-oxide-semiconductor field-effect transistor (NMOSFET) for example. Referring to FIG. 3, a transistor has different current-voltage characteristic curves under different gate-source voltages Vgs. In FIG. 3, where Vgs1>Vgs2>Vgs3>Vgs4, the dashed line on the right is drawn by connecting the breakdown voltages at different Vgs, and the dashed line on the left is drawn by connecting the turn-on voltages at different Vgs. The area between these two dashed lines is the safe operating area. When the transistor operates at a higher gate-source voltage Vgs, the breakdown voltage of the transistor is lower, meaning the transistor easier occurs breakdown. Therefore, by operating the transistor at a lower gate-source voltage Vgs or a less drain current Ids, the working point of the transistor will be farer from the corresponding breakdown voltage, meaning the transistor is relatively unlikely to break down. At the same time, however, the noise immunity of the transistor will be reduced.

U.S. Pat. No. 5,896,043 discloses an improved level shifter, in which two input transistors are each parallel-connected to a resistor-capacitor circuit, and in which currents to the input transistors is increased as soon as the input transistors are turned on, with a view to accelerating state transition. Nonetheless, this are requires even more complicated control.

### BRIEF SUMMARY OF THE INVENTION

An objective of the present invention is to improve a level shifter for a floating gate driver.

Another objective of the present invention is to provide a circuit and method for a level shifter to transmit a signal from the low side to the high side in current form.

Yet anther objective of the present invention is to provide a floating gate driver with better safe operating area and noise immunity.

According to the present invention, a level shifter for a floating gate driver is additionally provided with a high-voltage transistor and a current limiter connected in series between an input transistor and an output terminal, wherein the high-voltage transistor is always on. When the input transistor is turned on, a current pulse is generated and is transmitted to the output terminal. The current limiter limits the amplitude of the current pulse and thereby limits the gate-source voltage of the high-voltage transistor.

Since the level shifter transmits current-based signals, rather than voltage-based signals, from the low side to the high side, the noise immunity of the level shifter is enhanced.

The current limitation imposed on the current pulse limits the amplitude of the gate-source voltage of the high-voltage transistor and thus contributes to a better safe operating area.

### BRIEF DESCRIPTION OF THE DRAWINGS

These and other objectives, features and advantages of the present invention will become apparent to those skilled in the art upon consideration of the following description of the preferred embodiments of the present invention taken in conjunction with the accompanying drawings, in which:

FIG. 1 is a circuit diagram of a typical floating gate driver;

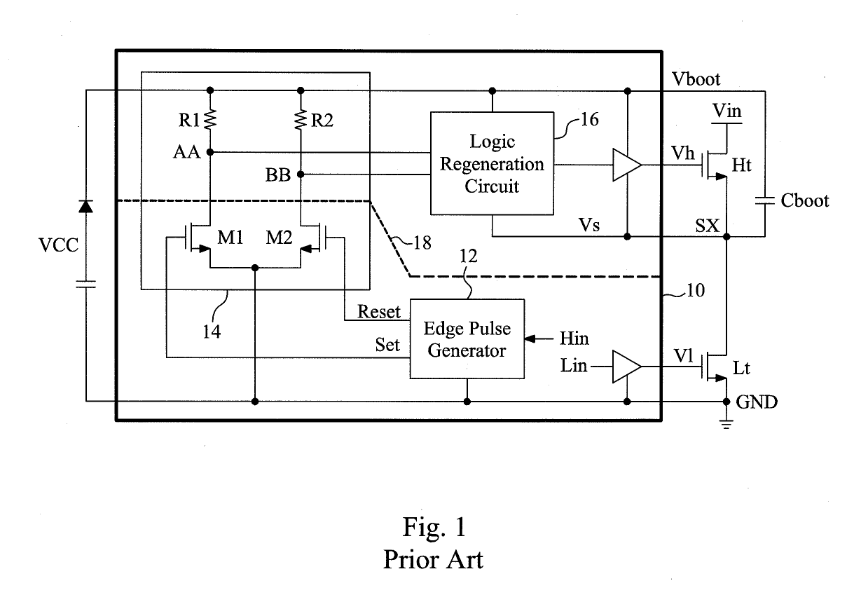

FIG. 2 is a waveform diagram showing how the floating gate driver shown in FIG. 1 shifts the level of a switch signal;

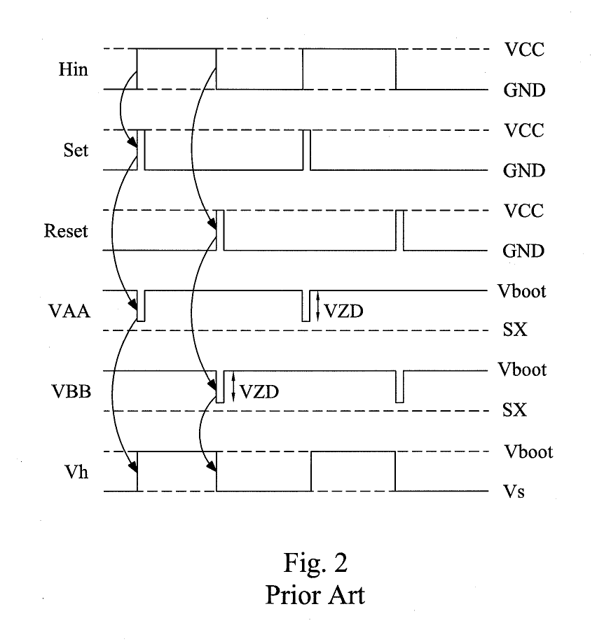

FIG. 3 is a diagram showing current-voltage characteristic curves and a safe operating area of an NMOSFET;

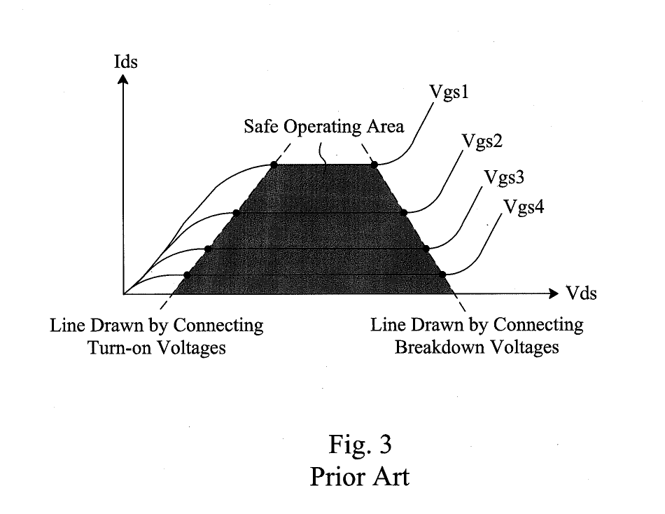

FIG. 4 is a circuit diagram of a first embodiment according to present invention;

FIG. 5 is a waveform diagram showing how the level shifter shown in FIG. 4 transmits a signal from low side to high side;

FIG. 6 is a circuit diagram of a second embodiment according to the present invention;

FIG. 7 is a circuit diagram of a third embodiment according to the present invention; and

FIG. 8 is a circuit diagram of a fourth embodiment according to the present invention.

### DETAILED DESCRIPTION OF THE INVENTION

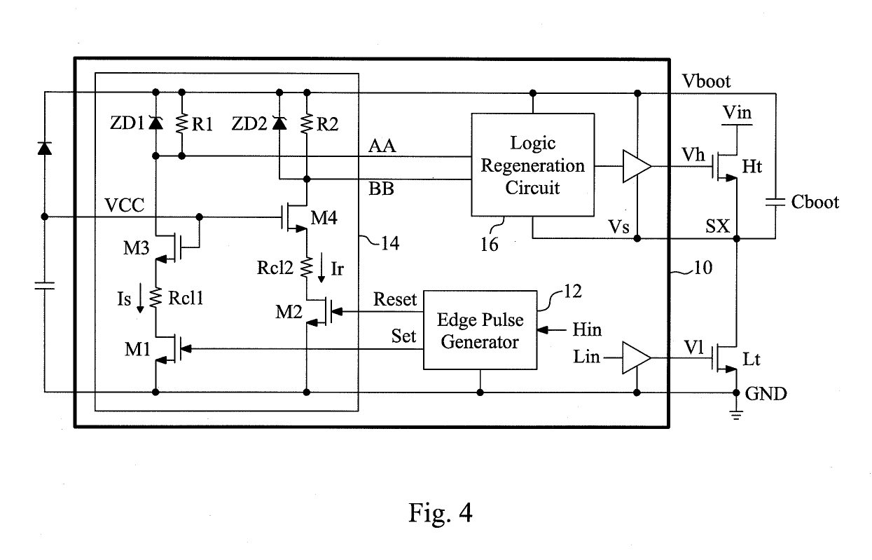

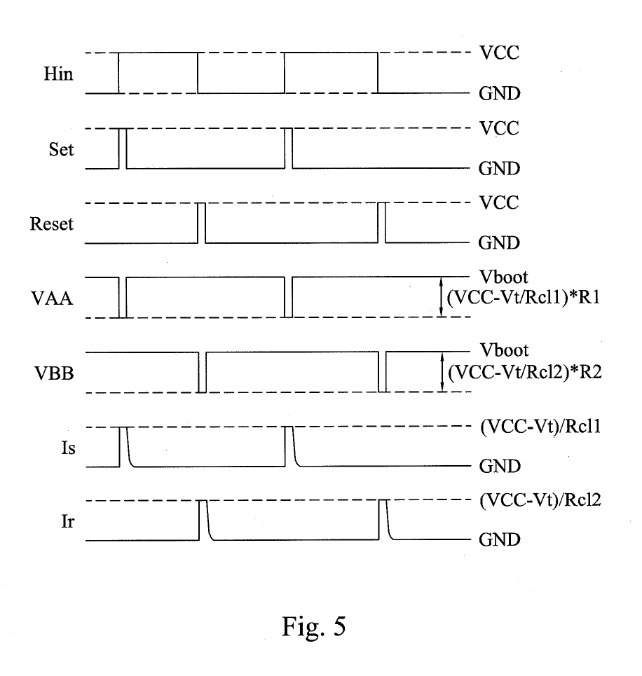

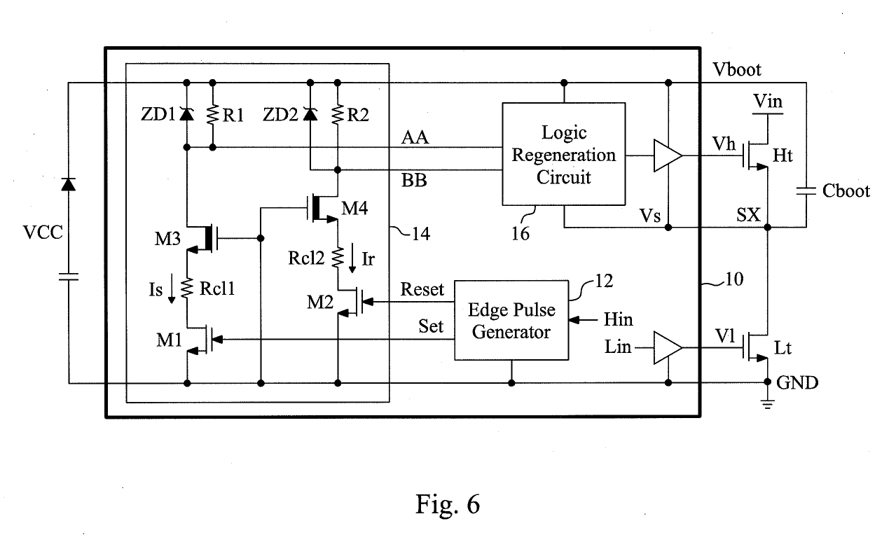

FIG. 4 is a circuit diagram of a first embodiment according to present invention, in which a high-voltage transistor M3 and a resistor Rcl1 are additionally connected in series between the input transistor M1 and the corresponding load R1, a high-voltage transistor M4 and a resistor Rcl2 are additionally connected in series between the input transistor M2 and the corresponding load R2, and the high-voltage transistors M3 and M4 are remained on, for example, by applying the DC input voltage VCC to their gates. Referring to FIG. 4 and FIG. 5, once the set signal Set turns on the input transistor M1, a current pulse Is=[(VCC−Vt)/Rcl1] is generated during the on time of the input transistor M1, after the input transistor M1 is turned off, the current pulse becomes Is=[(VCC−Vt)/Rcl1]×e^{-t/(Rp×Cp)}, where Vt is the threshold voltage of the high-voltage transistor M3, t is the time elapsed after the input transistor M1 is turned off, Rp is the sum of the current-limiting resistor Rcl1 and the on resistance of the input transistor M1, and Cp is the equivalent parasitic capacitance between the source of the high-voltage transistor M3 and the ground terminal GND, and in the output voltage VAA=Vboot−[(VCC−Vt)/Rcl1]×R1 at the output terminal AA is inserted with a negative voltage pulse Vset=(VCC−Vt/Rcl1)×R1. Once the reset signal Reset turns on the second input transistor M2, a current pulse Ir=[(VCC−Vt)/Rcl2] is generated during the on time of the input transistor M2, after the second input transistor M2 is turned off, the current pulse becomes Ir=[(VCC−Vt)/Rcl2]×e^{-t/(Rp×Cp)}, where Vt is the threshold voltage of the high-voltage transistor M4, t is the time elapsed after the input transistor M2 is turned off, Rp is the sum of the current-limiting resistor Rcl2 and the on resistance of the input transistor M2, and Cp is the equivalent parasitic capacitance between the source of the high-voltage transistor M4 and the ground terminal GND, and in the output voltage VBB=Vboot−[(VCC−Vt)/Rcl2]×R2 at the output terminal BB is inserted with a negative voltage pulse Vreset=(VCC−Vt/Rcl2)×R2. In other words, the level shifter 14 is changed to transmit signals from the low side to the high side in current form. In this embodiment, the resistors Rcl1 and Rcl2 serve as current limiters for limiting the amplitudes of the current pulses Is and Ir. When the resistance Rcl1 increases, the current pulse Is is decreased such that the gate-source voltage Vgs of the high-voltage transistor M3 is reduced; consequently, the safe operating area of the high-voltage transistor M3 is increased. Moreover, as the resistance Rcl1 increases, the negative voltage pulse Vset in the output voltage VAA is reduced in amplitude. Likewise, the resistor Rcl2 has the same effects on the safe operating area of the high-voltage transistor M4 and the amplitude of the negative voltage pulse Vreset in the output voltage VBB. In other embodiments, the resistors Rcl1 and Rcl2 may be replaced by other current limiters or circuits. Preferably, Zener diodes ZD1 and ZD2 are additionally provided and are connected in parallel to the resistors R1 and R2, respectively, so as to prevent the output voltages VAA and VBB from falling below a certain value. In this embodiment, each of the high-voltage transistors M3 and M4 is an enhancement-mode NMOSFET. In a different embodiment, the high-voltage transistors M3 and M4 are depletion-mode NMOSFETs instead, as shown in. FIG. 6, in which case the gates of the high-voltage transistors M3 and M4 are connected to the ground terminal GND instead, to keep the two high-voltage transistors remained on.

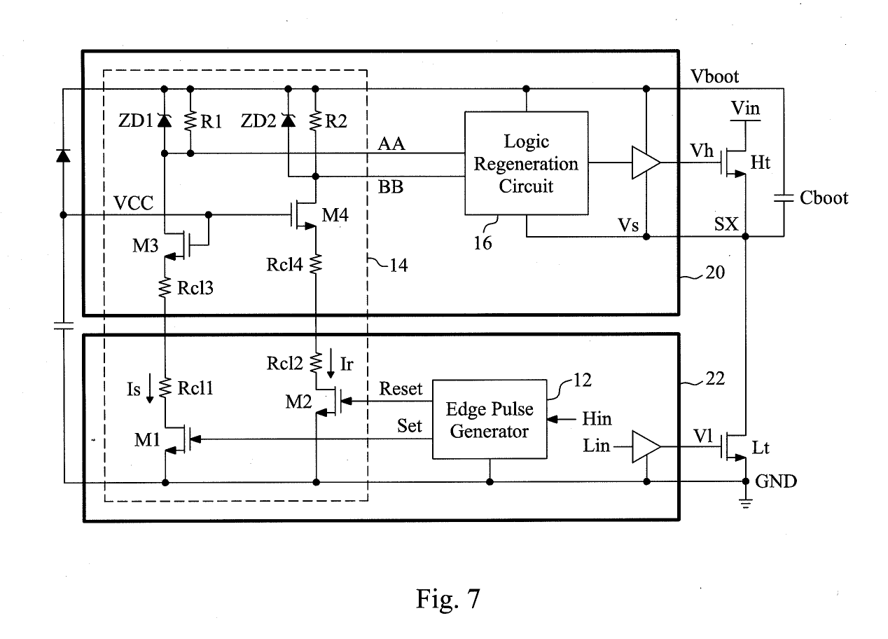

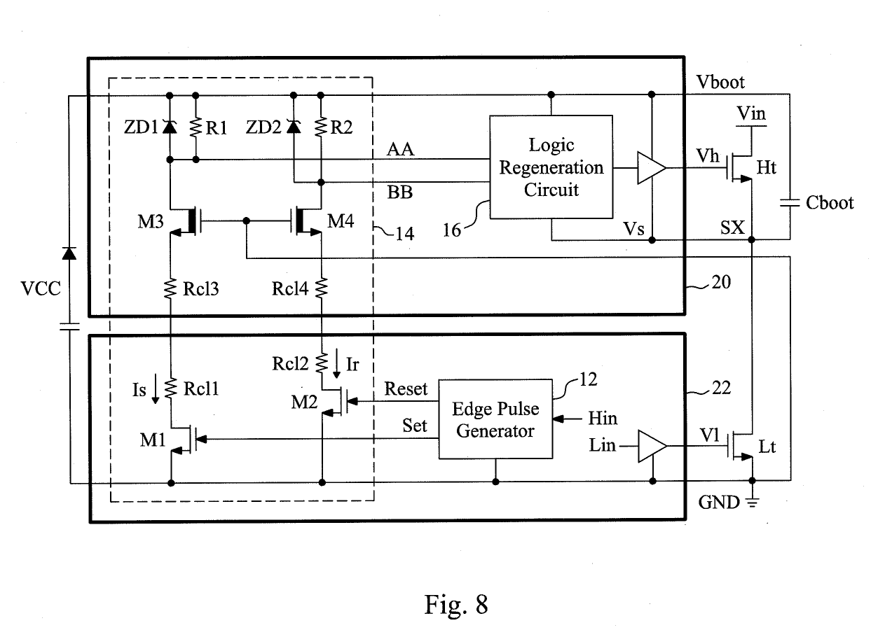

FIG. 7 is a circuit diagram of a third embodiment according to the present invention. In addition to the high-voltage transistors M3 and M4 as illustrated in the above embodiments, resistors Rcl3 and Rcl1 are connected in series between the high-voltage transistor M3 and the input transistor M1, and resistors Rcl4 and Rcl2 are connected in series between the high-voltage transistor M4 and the input transistor M2. Furthermore, the logic regeneration circuit 16, the high-voltage transistors M3 and M4, the Zener diodes ZD1 and ZD2, and the resistors R1, R2, Rcl3, and Rcl4 are integrated in a UHV chip 20, while the edge pulse generator 12, the input transistors M1 and M2, and the resistors Rcl1 and Rcl2 are integrated in a low-voltage chip 22. In this embodiment, an MCM is used to reduce costs, and the low noise immunity problem typical of MCMs is eliminated because the set signal Set and the reset signal Reset are transmitted from the low-voltage chip 22 to the UHV chip 20 in current form. Besides, both the UHV chip 20 and the low-voltage chip 22 have current limiting resistors. This allows the resistors Rcl3, Rcl4 in the UHV chip 20 and the resistors Rcl1, Rcl2 in the low-voltage chip 22 to be adjusted separately. For example, if the UHV chip 20 is so limited in space that the resistances Rcl3, Rcl4 cannot be increased, the resistances Rcl1, Rcl2 in the low-voltage chip 22 can be increased in order to achieve the desired effect. In other embodiments, one of the resistors Rcl1 and Rcl3 may be dispensed with, and so may one of the resistors Rcl2 and Rcl4. In this embodiment, each of the high-voltage transistors M3 and M4 is an enhancement-mode NMOSFET. In a different embodiment as shown in FIG. 8, the high-voltage transistors M3 and M4 are depletion-mode NMOSFETs, whose gates are connected to the ground terminal GND instead, to keep the two high-voltage transistors remained on.

As shown by the foregoing embodiments, the resistors Rcl1, Rcl2, Rcl3, and Rcl4 provide a current-limiting function that limits the amplitudes of the gate-source voltages Vgs of the high-voltage transistors M3 and M4. Hence, a better safe operating area can be obtained without increasing the sizes of the high-voltage transistors M3 and M4. Also, with the level shifter 14 transmitting current-based, rather than voltage-based, signals from the low side to the high side, the noise immunity of the level shifter 14 is improved. Not only that, an MCM may apply to further lower costs.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A floating gate driver, comprising:
an edge pulse generator detecting a rising edge and a falling edge of a switch signal to trigger a set signal and a reset signal, respectively;
a level shifter having a first input transistor and a second input transistor connected to the edge pulse generator for transmitting the set signal and the reset signal to a first output terminal and a second output terminal to generate a first negative voltage pulse and a second negative voltage pulse, respectively; and
a logic regeneration circuit connected to the first output terminal and the second output terminal, responsive to the first negative voltage pulse and the second negative voltage pulse to generate a signal as being level shifted from the switch signal;
wherein the level shifter further comprises:
a first high-voltage transistor and a second high-voltage transistor connected to the first output terminal and the second output terminal, respectively, and remained on;
a first current limiter connected between the first high-voltage transistor and the first input transistor; and
a second current limiter connected between the second high-voltage transistor and the second input transistor.

2. The floating gate driver of claim 1, wherein each of the first high-voltage transistor and the second high-voltage transistor is an enhancement-mode NMOSFET.

3. The floating gate driver of claim 1, wherein each of the first high-voltage transistor and the second high-voltage transistor is a depletion-mode NMOSFET.

4. The floating gate driver of claim 1, wherein each of the first current limiter and the second current limiter comprises a resistor.

5. The floating gate driver of claim 1, wherein the edge pulse generator, the level shifter, and the logic regeneration circuit are integrated in an ultra-high voltage chip.

6. The floating gate driver of claim 1, wherein the logic regeneration circuit, the first high-voltage transistor, and the second high-voltage transistor are integrated in an ultra-high voltage chip, and the edge pulse generator, the first input transistor, the second input transistor, the first current limiter, and the second current limiter are integrated in a low-voltage chip.

7. The floating gate driver of claim 1, wherein the logic regeneration circuit, the first high-voltage transistor, the second high-voltage transistor, the first current limiter, and the second current limiter are integrated in an ultra-high voltage chip, and the edge pulse generator, the first input transistor, and the second input transistor are integrated in a low-voltage chip.

8. The floating gate driver of claim 1, further comprising:
a third current limiter in series connection with the first current limiter between the first high-voltage transistor and the first input transistor; and
a fourth current limiter in series connection with the second current limiter between the second high-voltage transistor and the second input transistor.

9. The floating gate driver of claim 8, wherein the logic regeneration circuit, the first high-voltage transistor, the second high-voltage transistor, the third current limiter, and the fourth current limiter are integrated in an ultra-high voltage chip, and the edge pulse generator, the first input transistor, the second input transistor, the first current limiter, and the second current limiter are integrated in a low-voltage chip.

10. A method for level shifting a switch signal, comprising:
A.) detecting a rising edge and a falling edge of the switch signal to trigger a set signal and a reset signal, respectively;
B.) responsive to the set signal, generating a first current pulse;
C.) transmitting the first current pulse to a first output terminal;
D.) responsive to the first current pulse, generating a first negative voltage pulse at the first output terminal;
E.) responsive to the reset signal, generating a second current pulse;
F.) transmitting the second current pulse to a second output terminal;
G.) responsive to the second current pulse, generating a second negative voltage pulse at the second output terminal; and
H.) responsive to the first negative voltage pulse and the second negative voltage pulse, generating a signal as being level shifted from the switch signal.

11. The method of claim 10, wherein the step B comprises limiting an amplitude of the first current pulse, and the step E comprises limiting an amplitude of the second current pulse.

12. The method of claim 10, wherein the step C comprises transmitting the first current pulse from a low-voltage chip to an ultra-high voltage chip, and the step F comprises transmitting the second current pulse from the low-voltage chip to the ultra-high voltage chip.

13. The method of claim 10, wherein the step C comprises transmitting the first current pulse to the first output terminal via a first high-voltage transistor, and the step F comprises transmitting the second current pulse to the second output terminal via a second high-voltage transistor.

14. The method of claim 13, further comprising:
limiting a gate-source voltage of the first high-voltage transistor by the first current pulse; and
limiting a gate-source voltage of the second high-voltage transistor by the second current pulse.
